(19) United States
(12) Patent Application Publication
(10) Pub. No.: US 2009/0121363 A1
(43) Pub. Date: May 14, 2009

(54) Process for Producing Circuit Substrate and Circuit Substrate Obtained in Accordance With the Process

(75) Inventor: Masahito Nakabayashi, Saitama-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: LINTEC CORPORATION, Tokyo (JP)

(21) Appl. No.: 12/225,446

(22) PCT Filed: Mar. 20, 2007
(86) PCT No.: PCT/JP2007/056533

§ 371 Date: Sep. 22, 2008

(30) Foreign Application Priority Data
Mar. 31, 2006 (JP) 2006-097382

(51) Int. Cl. H01L 23/28; H01L 21/77

(52) U.S. Cl. 257/787; 438/127; 257/E21.598; 257/E23.116

(57) ABSTRACT

A process for producing a circuit substrate having a resin sheet having embedded circuit chips which is obtained by embedding circuit chips into a resin sheet, which comprises steps of (a) arranging and fixing circuit chips on a substrate for processing, (b) coating the substrate for processing on which the circuit chips have been arranged and fixed with a liquid material for forming a resin sheet of an energy curing type to form an uncured coating layer, (c) curing the uncured coating layer by impressing energy to form a layer of a resin sheet having embedded circuit chips, and (d) removing the substrate for processing from the layer of a resin sheet having embedded circuit chips, and a circuit substrate obtained in accordance with the process. A circuit substrate having a resin sheet having embedded circuit chips for controlling pixels of displays and the like can be produced efficiently with excellent quality and excellent productivity.

### TECHNICAL FIELD

The present invention relates to a process for producing a circuit substrate having a resin sheet having embedded circuit chips and a circuit substrate having a resin sheet having embedded circuit chips obtained in accordance with the process. More particularly, the present invention relates to a process for efficiently producing a circuit substrate having a resin sheet having embedded circuit chips for controlling pixels of displays and the like with excellent quality and excellent productivity and a circuit substrate having a resin sheet having embedded circuit chips which is produced in accordance with the process.

### BACKGROUND ART

Heretofore, in planar displays such as liquid crystal displays, for example, insulating films and semiconductor films are successively formed on a glass substrate in accordance with the CVD process (the chemical vapor deposition process), and a minute electronic device such as a thin film transistor (TFT) is formed in the vicinity of each pixel constituting images in accordance with the same process as that conducted for preparing a semiconductor integrated circuit. Switching on and off and controlling the density of each pixel are conducted by means of the electronic device. In other words, minute electronic devices such as TFT are prepared on the substrate used for the display when the display is produced. However, in the above process, it is inevitable that the process requires a great number of steps and is complicated, and the cost is high. When the area of the display is increased, the size of the CVD apparatus for forming films on the glass substrate is increased, and the cost is markedly increased.

To decrease the cost, a technology in which minute chips of integrated circuits of crystalline silicon are attached to a printing plate in a manner similar to that using a printing ink, and the attached chips are transferred to and fixed at prescribed positions on a substrate for the display using a means such as the printing technology, is disclosed (for example, refer to Patent Document 1). In this technology, a polymer film is formed on the substrate for the display in advance. Minute chips of integrated circuits of crystalline silicon are transferred to the polymer film using a means such as the printing technology, and the transferred chips are embedded into the polymer film in accordance with a process such as the heat molding or the heat pressing. However, the above process has drawbacks in that problems such as formation of strain and bubbles tend to arise in the polymer film, and that the process is not efficient since it takes a long time for the heating.

To overcome the above drawbacks, the present inventors have discovered a process in which a sheet for a circuit substrate comprising a macromolecular material of the energy ray curing type is used for embedding circuit chips (the specification of Japanese Patent Application No. 2005-120750). However, this technology is not always satisfactory since, occasionally, the air is left remaining in the vicinity of the circuit chips and on the surface of the sheet under some conditions of the embedding, and problems arise due to the remaining air.

[Patent Document 1] Japanese Patent Application Laid-Open No. 2003-248436

### DISCLOSURE OF THE INVENTION

Under the above circumstances, the present invention has an object of providing a process for efficiently producing a circuit substrate having a resin sheet having embedded circuit chips for controlling pixels of displays and the like with excellent quality and excellent productivity and a circuit substrate having a resin sheet having embedded circuit chips which is produced in accordance with the process.

As the result of intensive studies by the present inventors to achieve the above object, it was found that a circuit substrate having a resin sheet having embedded circuit chips could be produced efficiently with excellent quality and excellent productivity by arranging and fixing circuit chips on a substrate for processing, coating the substrate for processing with a liquid material for forming a resin sheet of the energy curing type to form an uncured coating layer, curing the uncured coating layer by impressing energy to form a layer of a resin sheet having embedded circuit chips, and removing the substrate for processing from the layer of a resin sheet having embedded circuit chips.

The present invention provides:

(1) A process for producing a circuit substrate having a resin sheet having embedded circuit chips which is obtained by embedding circuit chips into a resin sheet, which comprises steps of:
(a) arranging and fixing circuit chips on a substrate for processing, (b) coating the substrate for processing on which the circuit chips have been arranged and fixed with a liquid material for forming a resin sheet of an energy curing type to form an uncured coating layer, (c) curing the uncured coating layer by impressing energy to form a layer of a resin sheet having embedded circuit chips, and (d) removing the substrate for processing from the layer of a resin sheet having embedded circuit chips;
(2) The process for producing a circuit substrate described in (1), which comprises step (b′) between step (b) and step (c), said step (b′) comprising placing a support on the uncured coating layer;
(3) The process for producing a circuit substrate described in (2), which comprises step (d′) in combination with step (d), said step (d′) comprising removing the support from the layer of a resin sheet having embedded circuit chips;
(4) The process for producing a circuit substrate described in any one of (1) to (3), wherein the substrate for processing has a layer of a silicone-based resin on a surface thereof,
(5) The process for producing a circuit substrate described in any one of (1) to (4), wherein a thickness of the resin sheet having embedded circuit chips is 50 to 500 μm;
(6) The process for producing a circuit substrate described in any one of (1) to (5), wherein, in step (b), viscosity of the liquid material for forming a resin sheet of an energy curing type is 1 to 100,000 mPa·s when the liquid material is used for coating;
(7) The process for producing a circuit substrate described in any one of (1) to (6), wherein the liquid material for forming a resin sheet of an energy curing type is a material of a thermosetting type or a material of an active energy ray curing type; and
(8) A circuit substrate having a resin sheet having embedded circuit chips which is obtained in accordance with a process described in any one of (1) to (7).

### BRIEF DESCRIPTION OF THE DRAWINGS

FIG. 1A to FIG. 1D show process diagrams exhibiting an embodiment of the process for producing a circuit substrate having a resin sheet having embedded circuit chips of the present invention. FIG. 2 shows a diagram exhibiting the condition of an embedded chip. In the Figures, 1 means a substrate for processing, 2 means a resin layer, 3 means a circuit chip, 3′ means a chip, 4 means a spacer, 5 means a layer of a resin sheet or a resin sheet, 6 means a support, 7 means a layer of a release agent, and 10 means a circuit substrate.

### THE MOST PREFERRED EMBODIMENT TO CARRY OUT THE INVENTION

The process for producing a circuit substrate having a resin sheet having embedded circuit chips of the present invention (occasionally, referred to as the process for producing a circuit substrate, hereinafter) is a process for producing a circuit substrate having a resin sheet having embedded circuit chips which is obtained by embedding circuit chips into the resin sheet and is characterized in that the process comprises step (a), step (b), step (b′) conducted where desired, step (c), step (d) and step (d′) conducted where desired, which are described in the following.

[Step (a)]

This step is a step of arranging and fixing circuit chips on a substrate for processing.

The substrate for processing used in step (a) is not particularly limited as long as circuit chips can be arranged and fixed on the substrate and the substrate can be removed from the layer of a resin sheet having the embedded circuit chips after the layer of a resin sheet is cured, and various substrates can be used as the substrate for processing.

As the substrate for processing, for example, a glass substrate or a plastic substrate in the sheet form or a film form can be used. The thickness of the substrate for processing is not particularly limited. It is preferable that the thickness is, in general, about 20 μm to 5 mm and more preferably 50 μm to 2 mm from the standpoint of workability.

In the present invention, it is important that the surface of the substrate for processing at the side on which circuit chips are arranged and fixed (referred to as the front side of the substrate for processing, hereinafter) has the property such that the circuit chips can be fixed and the substrate for processing can be removed easily from the layer of a resin sheet having the embedded circuit chips after the layer of a resin sheet is cured.

For the above purpose, it is preferable that a resin layer having the above property is disposed on the front side of the substrate for processing. The resin layer having the above property is not particularly limited. For example, it is advantageous that a silicone-based resin layer, a polyolefin-based resin layer or a urethane resin layer is disposed. The silicone-based resin layer is preferable due to the excellent property for fixing the chip and the excellent property for removal from the resin sheet having an embedded chip after the resin sheet is cured.

As the silicone-based resin constituting the silicone-based resin layer, silicone-based resins of the addition reaction type are preferable. As the silicone-based resin of the addition reaction type, for example, silicone-based resins of the solvent type which comprise a polyorgano-siloxane having an alkenyl group such as vinyl group in the molecule as the main component, a polyorganohydrogensiloxane, a silicone resin, a catalyst such as a platinum-based compound and, where desired, a photopolymerization initiator are preferable.

The silicone-based resin layer can be formed by coating the front side of the substrate for processing with the silicone-based resin in accordance with a conventional process such as the bar coating process, the knife coating process, the roll coating process, the blade coating process, the die coating process and the gravure coating process, followed by drying the formed coating layer by heating or by irradiation with an active energy ray. As an alternative process, a silicone-based resin layer is formed by coating a film having a coating film of a releasing agent, such as a silicone modified with fluorine, with the silicone-based resin on the side having the layer of the releasing agent, followed by drying the formed coating layer by heating or by irradiation with an active energy ray, and the formed silicone-based resin layer is transferred to the front side of the substrate for processing.

The thickness of the silicone-based resin layer is, in general, 5 to 100 μm and preferably 10 to 50 μm from the standpoint of effectively fixing the circuit chip.

[(Step (b)]

In this step, a liquid material for forming a resin sheet of the energy curing type is applied to the substrate for processing on which the circuit chips have been arranged and fixed in the previous step (a) so that the circuit chips are coated with the liquid material, and an uncured coating layer is formed.

The liquid material for forming a resin sheet of the energy curing type used in step (b) include materials of the thermosetting type and materials of the active energy ray curing type.

As the liquid material for forming a resin sheet of the energy curing type, any liquid material for forming a resin sheet of the energy curing type can be used as long as the material is in the liquid state when the material is used for the coating, and any of liquid materials of the non-solvent type and liquid materials of the solvent type (in the form of a solution) can be used. The material may be brought into the liquid state by heating. The liquid material of the non-solvent type is preferable since the process can be simplified and the consumption of energy can be decreased due to the absence of the step of removing the solvent by drying after the coating.

Examples of the material for forming a resin sheet of the thermosetting type include resin compositions of the thermosetting type such as alkyd resin compositions, acrylic resin compositions of the thermosetting type, urethane resin compositions and epoxy resin compositions. Among the above materials, acrylic resin compositions of the thermosetting type are preferable from the standpoint of the optical properties.

As the alkyd resin composition, for example, resin compositions comprising (A) an alkyd resin, (B) a crosslinking agent and, where desired, (C) a curing catalyst can be used.

The alkyd resin of component (A) is not particularly limited and can be suitably selected from conventional resins known as the alkyd resins. The alkyd resin is a resin obtained by condensation of a polyhydric alcohol and a polybasic acid and includes non-convertible alkyd resins which are condensation products of a dibasic acid and a dihydric alcohol or condensation products of a dibasic acid and a dihydric alcohol modified with a fatty acid of a non-drying oil and convertible alkyd resins which are condensation products of a dibasic acid and an alcohol having a functionality of three or greater. Any of the above alkyd resins can be used in the present invention.

Examples of the polyhydric alcohol used as the material for the alkyd resin include dihydric alcohols such as ethylene glycol, diethylene glycol, triethylene glycol, propylene glycol, trimethylene glycol, tetramethylene glycol and neopentyl glycol; trihydric alcohols such as glycerol, trimethylolethane and trimethylolpropane; and polyhydric alcohols having a functionality of four or greater such as diglycerol, triglycerol, pentaerythritol, dipentaerythritol, mannitol and sorbitol. The polyhydric alcohol may be used singly or in combination of two or more.

Examples of the polybasic acid include aromatic polybasic acids such as phthalic anhydride, terephthalic acid, isophthalic acid and trimellitic anhydride; aliphatic saturated polybasic acids such as succinic acid, adipic acid and sebacic acid; aliphatic unsaturated polybasic acids such as maleic acid, maleic anhydride, fumaric acid, itaconic acid and citraconic anhydride; and polybasic acids obtained by the Diels-Alder reaction such as addition products of cyclopentadiene and maleic acid, addition products of terpene and maleic anhydride and addition products of rosin and maleic anhydride. The polybasic acid may be used singly or in combination of two or more.

As the modifier, for example, octylic acid, lauric acid, palmitic acid, stearic acid, oleic acid, linolic acid, linolenic acid, ereostearic acid, ricinoleic acid, dehydrated ricinoleic acid, oils such as coconut oil, linseed oil, tung oil, castor oil, dehydrated castor oil, soybean oil and safflower oil and fatty acid of these oils can be used. The modifier may be used singly or in combination of two or more.

In the present invention, the alkyd resin of component (A) may be used singly or in combination of two or more.

Examples of the crosslinking agent of component (B) include amino resins such as melamine resins and urea resins, urethane resins, epoxy resins and phenol resins.

The melamine resin can be produced by bringing melamine and formaldehyde into reaction with each other in the presence of a basic catalyst. The number of the primary and/or secondary amino group per the number of the triazine nucleus can be controlled by adjusting the relative amounts of melamine and formaldehyde.

In the present invention, a product obtained by bringing a suitable alcohol into reaction with the melamine resin obtained as described above in the presence of an acidic catalyst, where desired, to modify a portion of methylol group into an alkyl ether, may be used. As the alcohol used in the above reaction, lower alcohols are preferable. Examples of the lower alcohol include methyl alcohol and butyl alcohol. The type of the alcohol and the fraction of the modification to form ethers are not particularly limited and can be suitably selected with consideration on the compatibility with the alkyd resin, the solubility with the solvent and the curing property of the obtained resin composition.

In the present invention, the crosslinking agent of component (B) may be used singly or in combination of two or more.

In the resin composition, it is preferable that the ratio of the amounts of component (A) and component (B) expressed as the amount by mass of solid substances is in the range of 70:30 to 10:90. When the relative amount of component (A) exceeds the above range, the product of curing having the sufficient crosslinked structure cannot be obtained. When the relative amount of component (A) is less than the above range, the product of curing tends to be hard and brittle. It is preferable that the ratio of the amounts of component (A) and component (B) expressed as the amount by mass of solid substances is in the range of 65:35 to 10:90 and more preferably in the range of 60:40 to 20:80.

In the present invention, an acidic catalyst can be used as the curing catalyst of component (C).

The acidic catalyst is not particularly limited and can be suitably selected from conventional acidic catalysts which are known as the catalyst for the crosslinking reaction of alkyd resins. As the acidic catalyst, organic acidic catalysts such as p-toluenesulfonic acid and methanesulfonic acid are preferable. The acidic catalyst may be used singly or in combination of two or more. The amount of the acidic catalyst is selected, in general, in the range of 0.1 to 40 parts by mass, preferably in the range of 0.5 to 30 parts by mass and more preferably in the range of 1 to 20 parts by mass per 100 parts by mass of the sum of the amounts of component (A) and component (B).

The resin composition may be a composition of the non-solvent type or a composition of the solvent type as long as the resin composition is in the liquid state when the resin composition is used for the coating. As the organic solvent used for the composition of the solvent type, an organic solvent is suitably selected from conventional solvents which exhibit excellent solubility with and are inert to component (A) and component (B). Examples of the solvent include toluene, xylene, methanol, ethanol, isobutanol, n-butanol, acetone, methyl ethyl ketone and tetrahydrofuran. The solvent may be used singly or in combination of two or more.

The resin composition can be obtained by adding component (A), component (B) and component (C), which is used where desired, in each prescribed amount into the organic solvent, followed by adjusting the viscosity to a value allowing the coating operation. Additive components used in this preparation are not particularly limited and can be suitably selected from conventional additive components which are known as the additive components of alkyd resins. For example, antistatic agents such as cationic surfactants and other resins for adjusting flexibility and viscosity such as acrylic resins can be used.

Examples of the acrylic resin composition of the thermosetting type include (1) acrylic resin composition (I) comprising a (meth)acrylic acid ester-based copolymer having a crosslinkable functional group and a crosslinking agent and (2) acrylic resin composition (II) comprising a radical polymerizable acrylic monomer and/or a radical polymerizable acrylic oligomer and a polymerization initiator which is used where desired.

As the (meth)acrylic acid ester-based copolymer having a crosslinkable functional group in acrylic resin composition (I), copolymers of a (meth)acrylic acid ester having an alkyl group having 1 to 20 carbon atoms in the ester portion, a monomer having a functional group having active hydrogen and other monomers which are used where desired, are preferable. The (meth)acrylic acid ester means a methacrylic acid ester and/or an acrylic acid ester.

Examples of the (meth)acrylic acid ester having an alkyl group having 1 to 20 carbon atoms in the ester portion include methyl (meth)acrylate, ethyl (meth)acrylate, propyl (meth)acrylate, butyl (meth)acrylate, pentyl (meth)acrylate, hexyl (meth)acrylate, cyclohexyl (meth)acrylate, 2-ethylhexyl (meth)acrylate, isooctyl (meth)acrylate, decyl (meth)acrylate, dodecyl (meth)acrylate, myristyl (meth)acrylate, palmityl (meth)acrylate and stearyl (meth)acrylate. The above compound may be used singly or in combination of two or more.

Examples of the monomer having a functional group having active hydrogen include hydroxyalkyl (meth)acrylates such as 2-hydroxyethyl (meth)acrylate, 2-hydroxypropyl (meth)acrylate, 3-hydroxypropyl (meth)-acrylate, 2-hydroxybutyl (meth)acrylate, 3-hydroxybutyl (meth)acrylate and 4-hydroxybutyl (meth)acrylate; monoalkylaminoalkyl (meth)acrylates such as monomethylaminoethyl (meth)acrylate, monoethylaminoethyl (meth)acrylate, monomethylaminopropyl (meth)acrylate and monoethyl-aminopropyl (meth)acrylate; and ethylenically unsaturated carboxylic acids such as acrylic acid, methacrylic acid, crotonic acid, maleic acid, itaconic acid and citraconic acid. The above monomer may be used singly or in combination of two or more.

Examples of the other monomer which is used where desired include vinyl esters such as vinyl acetate and vinyl propionate; olefins such as ethylene, propylene and isobutylene; halogenated olefins such as vinyl chloride and vinylidene chloride; styrene-based monomers such as styrene and α-methylstyrene; diene-based monomers such as butadiene, isoprene and chloroprene; nitrile-based monomers such as acrylonitrile and methacrylonitrile; and acrylamides such as acrylamide, N-methyl-acrylamide and N,N-dimethylacrylamide. The other monomer may be used singly or in combination of two or more.

In acrylic resin composition (I), the form of copolymerization of the (meth)acrylic acid ester-based copolymer used as the resin component is not particularly limited, and the (meth)acrylic acid ester-based copolymer may be any of a random copolymer, a block copolymer and a graft copolymers. It is preferable that the molecular weight is 300,000 or greater as the weight-average molecular weight.

The weight-average molecular weight is the value obtained by the measurement in accordance with the gel permeation chromatography (GPC) and expressed as the value of the corresponding polystyrene.

In the present invention, the (meth)acrylic acid ester may be used singly or in combination of two or more.

The crosslinking agent in acrylic resin composition (I) is not particularly limited, and a crosslinking agent may be suitably selected as desired from the conventional crosslinking agents used for acrylic resins. Examples of the crosslinking agent include polyisocyanate compounds, epoxy resins, melamine resins, urea resins, dialdehydes, methylol polymers, aziridine-based compounds, metal chelate compounds, metal alkoxides and metal salts. Among these compounds, polyisocyanate compounds are preferable.

Examples of the polyisocyanate compound include aromatic polyisocyanates such as tolylene diisocyanate, diphenylmethane diisocyanate and xylylene diisocyanate; aliphatic polyisocyanates such as hexamethylene diisocyanate; alicyclic polyisocyanates such as isophorone diisocyanate and hydrogenated diphenylmethane diisocyanate; biuret compounds and isocyanurate compounds of these polyisocyanates; and adducts which are reaction products of these polyisocyanates with low molecular weight compounds having active hydrogen such as ethylene glycol, propylene glycol, neopentyl glycol, trimethylolpropane and castor oil.

In the present invention, the crosslinking agent may be used singly or in combination of two or more. The amount of the crosslinking agent is selected, in general, in the range of 0.01 to 20 parts by mass and preferably in the range of 0.1 to 10 parts by mass per 100 parts by mass of the (meth)acrylic acid ester-based copolymer although the amount may be different depending on the type of the crosslinking agent.

Acrylic resin composition (I) may further comprise various additives such as antioxidants, ultraviolet light absorbents, light stabilizers, softeners, filler and coloring agents where desired as long as the object of the present invention is not adversely affected. Acrylic resin composition (I) may further comprise a suitable solvent. Examples of the solvent include toluene, xylene, methanol, ethanol, isobutanol, n-butanol, acetone, methyl ethyl ketone and tetrahydrofuran.

Examples of the acrylic monomer in acrylic resin composition (II) include monofunctional acrylates such as cyclohexyl (meth)acrylate, 2-ethylhexyl (meth)acrylate, lauryl (meth)acrylate, stearyl (meth)acrylate and isobornyl (meth)acrylate; and polyfunctional acrylates such as 1,4-dibutanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol hydroxy-pivalate di(meth)acrylate, dicyclopentanyl di(meth)acrylate, dimethylol-tricyclodecane di(meth)acrylate, dicyclopentenyl di(meth)acrylate modified with caprolactone, phosphoric acid di(meth)acrylate modified with ethylene oxide, cyclohexyl di(meth)acrylate modified with allyl group, isocyanurate di(meth)acrylate, trimethylolpropane tri(meth)acrylate, dipentaerythritol tri(meth)acrylate, dipentaerythritol tri(meth)acrylate modified with propionic acid, pentaerythritol tri(meth)acrylate, trimethylolpropane tri(meth)acrylate modified with propylene oxide, tris(acryloxyethyl)isocyanurate, dipentaerythritol penta(meth)acrylate modified with propionic acid, dipentaerythritol hexa(meth)acrylate and dipentaerythritol hexa(meth)acrylate modified with caprolactone. The above polymerizable monomer may be used singly or in combination of two or more.

Examples of the radical polymerizable oligomer include polyester acrylate-based oligomers, epoxyacrylate-based oligomers, urethane acrylate-based oligomers and polyol acrylate-based oligomers.

The polyester acrylate-based oligomer can be obtained, for example, by obtaining a polyester oligomer having hydroxyl groups at both ends by condensation of a polybasic carboxylic acid with a polyhydric alcohol, followed by esterification of the hydroxyl groups in the obtained oligomer with (meth)acrylic acid; or by obtaining an oligomer having hydroxyl groups at both ends by addition of an alkylene oxide to a polybasic carboxylic acid, followed by esterification of the hydroxyl groups of the obtained oligomer with (meth)acrylic acid. The epoxyacrylate-based prepolymer can be obtained, for example, by esterification of oxirane rings in an epoxy resin of the bisphenol type or an epoxy resin of the novolak type having a relatively low molecular weight by the reaction with (meth)acrylic acid. The urethane acrylate-based prepolymer can be obtained, for example, by obtaining a polyurethane oligomer by the reaction of a polyether polyol or a polyester polyol with a polyisocyanate, followed by esterification of the obtained oligomer with (meth)acrylic acid. The polyol acrylate-based prepolymer can be obtained, for example, by esterification of hydroxyl groups in a polyether polyol with (meth)acrylic acid. The above polymerizable oligomer may be used singly, in combination of two or more or in combination with the acrylic monomer described above.

In acrylic resin composition (II), an organic peroxide or an azo-based compound is used as the polymerization initiator which is used as desired. Examples of the organic peroxide include dialkyl peroxides such as di-t-butyl peroxide, t-butyl cumyl peroxide and dicumyl peroxide; diacyl peroxides such as acetyl peroxide, lauroyl peroxide and benzoyl peroxide; ketone peroxides such as methyl ethyl ketone peroxide, cyclohexanone peroxide, 3,3,5-trimethylcyclohexanone peroxide and methylcyclohexanone peroxide; peroxyketals such as 1,1-bis(t-butyl-peroxy)cyclohexane; hydroperoxides such as t-butyl hydroperoxide, cumene hydroperoxide, 1,1,3,3-tetramethylbutyl hydroperoxide, p-menthane hydroperoxide, diisopropylbenzene hydroperoxide and 2,5-dimethylhexane 2,5-dihydroperoxide; and peroxyesters such as t-butyl peroxyacetate, t-butyl peroxy-2-ethylhexanoate, t-butyl peroxybenzoate, t-butyl peroxyisopropylcarbonate and t-butyl peroxy-3,3,5-trimethyl-hexanoate.

Examples of the azo-based compound include 2,2′-azobis-(4-methoxy-2,4-dimethylvaleronitrile), 2,2′-azobis(2-cyclopropylpropio-nitrile), 2,2′-azobis(2,4-dimethylvaleronitrile), azobisisobutyronitrile, 2,2′-azobis(2-methylbutyronitrile), 1,1′-azobis(cyclohexane-1-carbonitrile), 2-(carbamoylazo)isobutyronitrile and 2-phenylazo-4-methoxy-2,4-dimethylvaleronitrile.

The polymerization initiator may be used singly or in combination of two or more.

Acrylic resin composition (II) can be prepared by adding the radical polymerizable acrylic monomer and/or oligomer, the polymerization initiator and various additives which are used where desired such as antioxidants, ultraviolet light absorbents, light stabilizers, leveling agents and defoaming agents in each prescribed amount into a suitable solvent, followed by dissolving or dispersing the components into the solvent.

Examples of the material for forming a resin sheet of the active energy ray curing type include resin compositions of the active energy ray curing type comprising a polymerizable compound of the active energy ray curing type and, where desired, a photopolymerization initiator. As the polymerizable compound of the active energy ray curing type, a single compound or a combination of two or more compounds are selected from monomers polymerizable with active energy ray, oligomers polymerizable with active energy ray and polymers polymerizable with active energy ray.

The compound polymerizable with active energy ray means a polymerizable compound which is crosslinked and cured by irradiation with ray having energy quantum among electromagnetic waves and beams of charged particles, i.e., ultraviolet light or electron beams.

Examples of the monomer polymerizable with active energy ray include monofunctional acrylates and polyfunctional acrylates, which are the compounds described as the examples of the radical polymerizable acrylic monomer in the description of acrylic resin composition (II) in the above, and cationic polymerizable monomers. Examples of the cationic polymerizable monomer include alkenes substituted with alkyl groups such as indene and coumarone; styrene derivatives such as styrene and α-methylstyrene; vinyl ethers such as ethyl vinyl ether, n-butyl vinyl ether, cyclohexyl vinyl ether, butanediol divinyl ether and diethylene glycol divinyl ether; glycidyl ethers such as bisphenol A diglycidyl ether, bisphenol F diglycidyl ether and ethylene glycol diglycidyl ether; oxetanes such as 3-ethyl-3-hydroxyethyloxetane and 1,4-bis[(3-ethyl-3-oxetanyl-methoxy)methyl]benzene; alicyclic epoxy compounds such as 3,4-epoxy-cyclohexylmethyl (3,4-epoxy)cyclohexanecarboxylate and bis(3,4-epoxy-cylohexyl) adipate; and N-vinylcarbazole.

The cationic polymerizable monomer may be used singly or in combination of two or more.

The oligomer polymerizable with active energy ray includes oligomers of the radical polymerization type and oligomers of the cationic polymerization type. Examples of the oligomer polymerizable with active energy ray of the radical polymerization type include polyester acrylate-based oligomers, epoxy acrylate-based oligomers, urethane acrylate-based oligomers and polyol acrylate-based oligomers. Examples of the polymer polymerizable with active energy ray include (meth)acrylic acid ester-based copolymers having a group curable with energy ray such as (meth)acryloyl group in the side chain.

Examples of the oligomer polymerizable with active energy ray of the radical polymerization type include the compounds described as the examples of the radical polymerizable acrylic oligomer in the description of acrylic resin composition (II) in the above.

Examples of the oligomer polymerizable with active energy ray of the cationic polymerization type include epoxy-based resins, oxetane-based resins and vinyl ether resins. Examples of the epoxy-based resin include compounds obtained by epoxidation of polyfunctional phenol compounds with epichlorohydrin such as bisphenol resins and novolak resins and compounds obtained by oxidation of linear olefin compounds and cyclic olefin compounds with peroxides.

Examples of the photopolymerization initiator used for oligomers and monomers polymerizable with active energy ray such as photopolymerizable oligomers and monomers of the radical polymerization type include benzoin, benzoin methyl ether, benzoin ethyl ether, benzoin isopropyl ether, benzoin n-butyl ether, benzoin isobutyl ether, acetophenone, dimethylaminoacetophenone, 2,2-dimethoxy-2-phenyl-acetophenone, 2,2-diethoxy-2-phenylacetophenone, 2-hydroxy-2-methyl-1-phenylpropan-1-one, 2,2-dimethoxy-1,2-diphenylethan-1-one, 1-hydroxy-cyclohexyl phenyl ketone, 2-methyl-1-[4-(methylthio)phenyl]-2-morpholinopropan-1-one, 4-(2-hydroxyethoxy)phenyl 2-(hydroxy-2-propyl) ketone, benzophenone, p-phenylbenzophenone, 4,4′-diethylamino-benzophenone, dichlorobenzophenone, 2-methylanthraquinone, 2-ethyl-anthraquinone, 2-tertiary-butylanthraquinone, 2-aminoanthraquinone, 2-methylthioxanthone, 2-ethylthioxanthone, 2-chlorothioxanthone, 2,4-dimethylthioxanthone, 2,4-diethylthioxanthone, benzyl dimethylketal, acetophenone dimethylketal and p-dimethylaminebenzoic acid ester. Examples of the photopolymerization initiator used for the photo-polymerizable oligomers and monomers of the cationic polymerization type include compounds comprising an onium such as an aromatic sulfonium ion, an aromatic oxosulfonium ion and an aromatic iodonium ion and an anion such as tetrafluoroborate, hexafluorophosphate, hexafluoroantimonate and hexafluoroarsenate. The above compound may be used singly or in combination of two or more. The amount of the above compound is, in general, in the range of 0.2 to 10 parts by mass per 100 parts by mass of the photopolymerizable monomer and/or the photopolymerizable oligomer.

The material for forming a resin sheet of the active energy ray curing type of the present invention may be a material of the non-solvent type or a material of the solvent type as long as the material is in the liquid state when the material is used for the coating. When the material for forming a resin sheet of the active energy ray curing type is a material of the solvent type, the material can be prepared by adding the polymerizable compound of the active energy ray curing type described above and, where desired, the photopolymerization initiator and various added components such as antioxidants, ultraviolet light absorbents, light stabilizers, leveling agents, defoaming agents, coloring agents and crosslinking agents in each prescribed amount into a suitable solvent, followed by dissolving or dispersing the components into the solvent.

Examples of the solvent used in the above preparation include aliphatic hydrocarbons such as hexane and heptane; aromatic hydrocarbons such as toluene and xylene; halogenated hydrocarbons such as methylene chloride and ethylene chloride; alcohols such as methanol, ethanol, propanol and butanol; ketones such as acetone, methyl ethyl ketone, 2-pentanone, isophorone and cyclohexanone; esters such as ethyl acetate and butyl acetate; and cellosolve-based solvents such as ethylcellosolve.

In step (b), the liquid material for forming a resin sheet of the energy curing type prepared as described above is applied to the substrate for processing on which the circuit chips have been arranged and fixed in the previous step (a) so that the circuit chips are coated with the liquid material, and an uncured coating layer is formed. For the coating, a coating process which does not cause movements of the circuit chips from the fixed positions such as the solution casting process can be used.

Specifically, spacers having a prescribed thickness are disposed at both end portions of the substrate for processing, and the solution casting of the material for forming a resin sheet of the energy curing type is conducted to form the uncured coating layer. When the material for forming a resin sheet is a material of the solvent type, the uncured coating layer formed above may be further treated by drying at a suitable temperature to form the desired uncured coating layer.

The viscosity of the material for forming a resin sheet of the energy curing type when the material is used for the coating is, in general, 1 to 100,000 mPa·s and preferably 50 to 50,000 mPa·s from the standpoint of the workability.

[Step (b′)]

This step is conducted where necessary. In this step, a support is placed on the uncured coating layer formed in step (b) described above. Depending on the application, a structure in which the resin sheet having embedded circuit chips is laminated to a support may be occasionally required for the circuit substrate obtained in accordance with the process of the present invention. In this case, the support becomes a member of the circuit substrate.

The support may be used as a protective layer when a layer of the resin sheet having embedded circuit chips is formed by curing the uncured coating layer by impressing energy in the following step (c). In this case, the support is removed from the layer of the resin sheet having embedded circuit chips after step (c) is completed.

When the support is used for exhibiting the function of the protective layer as described above, the support is not particularly limited. Examples of the support include glass plates and plastic supports in the sheet form or in the film form, which have a suitable thickness. When the uncured coating layer is cured by irradiation with active energy ray in the following step (c), a substance transmitting the active energy ray is used as the support. The surface of the support at the side contacting the uncured coating layer may have a suitable releasing treatment so that removal of the support from the layer of a resin sheet having embedded circuit chips is facilitated.

When the support is used as a member of the obtained circuit substrate, the support is not particularly limited, and a suitable substance can be selected as desired from conventional transparent supports used as the support for displays. Examples of the support include glass plates and plastic supports in the sheet form or in the film form. Examples of the glass plate used as the support include plates of soda lime glass, glass containing barium and strontium, aluminosilicate glass, lead glass, borosilicate glass, barium borosilicate glass and quartz. Examples of the plastic support in the sheet form or in the film form include supports of polycarbonate resins, acrylic resins, polyethylene terephthalate resins, polyether sulfide resins, polysulfone resins and polycycloolefin resins.

The thickness of the support is, in general, about 20 μm to 5 mm and preferably 50 μm to 2 mm although the thickness is suitably selected in accordance with the application.

When the support is the plastic support in the sheet form or in the film form, the face of the support contacting the uncured coating layer may have a surface treatment such as the oxidation treatment or the roughening treatment or a primer treatment so that adhesion with the resin sheet having embedded circuit chips is enhanced. Examples of the oxidation treatment include the treatment by corona discharge, the treatment by plasma discharge, the treatment with chromic acid (a wet process), the treatment with flame and the treatment with ozone and ultraviolet light. Examples of the roughening treatment include the sand blasting treatment and the treatment with a solvent. The surface treatment is suitably selected in accordance with the type of the support. In general, the treatment by corona discharge is preferable from the standpoint of the effect and the workability.

[Step (c)]

Step (c) is the step in which energy is impressed to the uncured coating layer formed in the previous step (b) to cure the coating layer, and a layer of the resin sheet having embedded circuit chips is formed.

In step (c), when the uncured coating layer is formed using a material for forming a resin sheet of the thermosetting type, the uncured coating layer is cured by the heat treatment, in general, at a temperature of about 80 to 150° C. and preferably at a temperature of 100 to 130° C. for a time of several tens seconds to several hours, and the layer of a resin sheet having embedded circuit chips is formed.

When the uncured coating layer is formed using a material for forming a resin sheet of the active energy ray curing type, the uncured coating layer is cured by irradiation with an active energy ray, and a layer of the resin sheet having embedded circuit chips is formed.

As the active energy ray, in general, ultraviolet light or electron beams are used. Ultraviolet light can be obtained from a metal halide lamp, a high pressure mercury lamp, a fusion H lamp or a xenon lamp. The electron beams are obtained from an electron beam accelerator. Among these active energy rays, ultraviolet light is preferable. The amount of the active energy ray used for the irradiation can be suitably selected. For example, it is preferable that the quantity of the light is 100 to 500 mJ/cm² and the luminance is 10 to 500 mW/cm² when ultraviolet light is used, and the dose is about 10 to 1,000 krad when electron beams are used.

[Step (d)]

Step (d) is a step in which the substrate for processing is removed from the layer of the resin sheet having embedded circuit chips formed in the above step (c).

When step (b′) comprising placing a support on the uncured coating layer is not conducted, the circuit substrate comprising the resin sheet having embedded circuit chips is obtained in the present step (d).

When the above step (b′) is conducted and the support is used as a member of the circuit substrate, the circuit substrate in which the resin sheet having embedded circuit chips is placed on the support is obtained in the present step (d).

[Step (d′)]

Step (d′) is a step conducted in combination with step (d) where necessary, and the support is removed from the layer of the resin sheet having embedded circuit chips.

When the support used as the protective layer is placed on the uncured coating layer in step (b′), the support is removed from the layer of the resin sheet having embedded circuit chips in the present step (d′). The circuit substrate comprising the resin sheet having embedded circuit chips is obtained by the above procedure.

In the circuit substrate obtained as described above, the thickness of the resin sheet having embedded circuit chips is, in general, about 30 μm to 2 mm and preferably 50 to 500 μm.

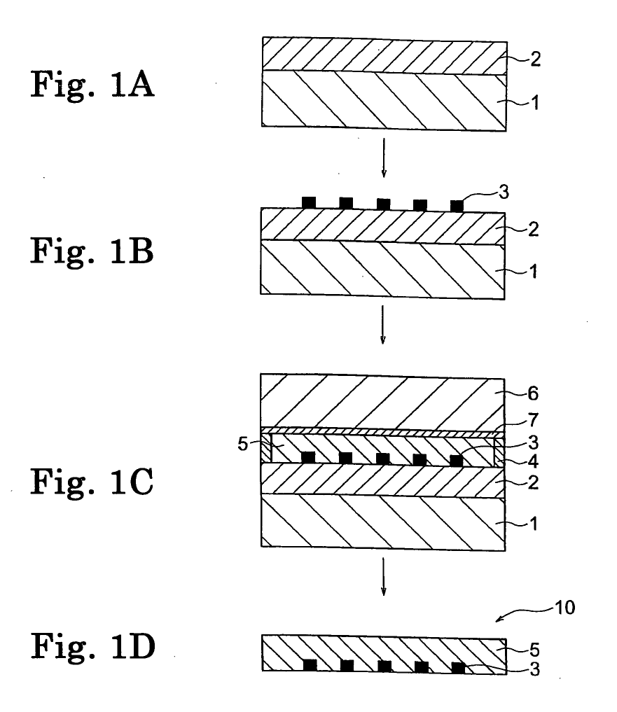

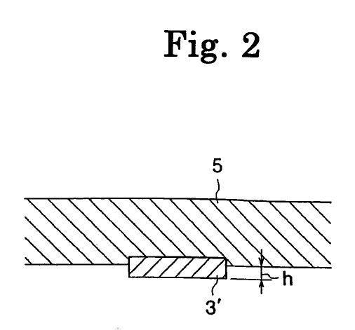

FIGS. 1A to 1D show process diagrams exhibiting an embodiment of the process for producing a circuit substrate having a resin sheet having embedded circuit chips of the present invention

A substrate for processing 1 having at the front side a resin layer 2 on which circuit chips can be fixed is used [FIG. 1A]. Circuit chips 3 are arranged and fixed on the resin layer 2 on the substrate for processing 1 [FIG. 1B]. After spacers 4 are laminated to the resin layer 2 on the substrate for processing 1, the solution casting of a material for forming a resin sheet of the energy curing type is conducted, and an uncured coating layer is formed. After a support 6 having a release layer 7 is placed on the uncured coating layer in a manner such that the releasing layer 7 faces the uncured coating layer, the uncured coating layer is cured by impressing energy, and a layer of a resin sheet 5 having embedded circuit chips 3 is formed [FIG. 1C].

In the final step, the substrate for processing 1 is removed from the layer of a resin sheet 5 having embedded circuit chips 3 in combination with the resin layer 2. Then, the support 6 is removed, and a circuit substrate 10 comprising the resin sheet 5 having embedded circuit chips 3 is obtained [FIG. 1D].

In accordance with the process of the present invention described above, the amount of the air left remaining in the vicinity of the circuit chip and on the surface of the sheet is suppressed, and the circuit substrate comprising a resin sheet having embedded circuit chips can be efficiently produced with excellent quality and excellent productivity.

The circuit substrate comprising a resin sheet having embedded circuit chips obtained in accordance with the process of the present invention is advantageously used for controlling pixels in displays and the like.

The present invention also provides a circuit substrate comprising a resin sheet having embedded circuit chips obtained in accordance with the process of the present invention described above.

### EXAMPLES

The present invention will be described more specifically with reference to examples in the following. However, the present invention is not limited to the examples.

The property for embedding of a resin sheet having embedded circuit chips obtained in Examples was evaluated in accordance with the following method.

### (1) Property for Embedding

Resin sheets having embedded circuit chips obtained in Examples were observed using a confocal microscope [manufactured by Lasertec Corporation; the trade name: “HD100D”]. The presence or the absence of a gap between a chip and the resin was examined, and the amount of protrusion h shown in FIG. 2 was measured. The property for embedding was evaluated based on the results. In FIG. 2, the mark 3′ means a chip, and the mark 5 means a resin sheet.

Two resin sheets having embedded circuit chips were prepared for each type of the resin sheet. In each resin sheet, 25 chips were observed (50 chips in two resin sheets), and the number of the chip having a gap between the chip and the resin and the maximum value and the average of the amount of protrusion were obtained. The property for embedding was evaluated as excellent when the maximum value of the amount of protrusion was 20 μm or smaller and the average of the amount of protrusion was 10 μm or smaller.

### Example 1

### (1) Formation of a Silicone-Based Resin Layer on a Glass Substrate for Processing

To 100 parts by mass of a polyorganosiloxane of the addition type having the siloxane bond as the skeleton structure and containing polyorganosiloxane having vinyl group and polyorganohydrogensiloxane [manufactured by Shin-Etsu Chemical Co., Ltd.; the trade name: “KS-847H”], 10 parts by mass of a silicone resin component [manufactured by Shin-Etsu Chemical Co., Ltd.; the trade name: “KR3700”] and 0.2 parts by mass of a platinum catalyst [manufactured by TORAY DOW CORNING Co., Ltd.; the trade name: “SRX-212”] were added, and a solution of a silicone-based resin having a concentration of solid components of 20% by mass was prepared by adding methyl ethyl ketone.

The solution of a silicone-based resin prepared above was applied to one face of a glass substrate having a thickness of 0.7 mm [manufactured by Corning Incorporated; the trade name: “1737”] which had been cut to a size of 100 mm×100 mm and was used as the substrate for processing. The formed coating layer was dried at 130° C. for 2 minutes, and a silicone-based resin layer having a thickness of 30 μm after being dried was formed.

### (2) Arranging and Fixing Chips on the Silicone-Based Resin Layer

A silicon mirror wafer which had been ground to a thickness of 50 μm was diced to form pieces having a size of 1.5 mm×1.5 mm, and the obtained pieces were used as dummies for the circuit chips. The obtained chips were arranged on the silicone-based resin layer formed in (1) described above in a manner such that the chips were placed at a distance of 1 cm from each other in an arrangement in 5 columns and 5 rows (25 chips). A glass substrate (the same glass substrate as that used as the glass substrate for processing in the above) was placed on the arranged chips and pressed by hands to fix the chips and, then, the glass plate was removed.

### (3) Coating with a Resin Composition of the Ultraviolet Light Curing Type, Curing of the Composition and Separation of a Resin Sheet Having Embedded Chips

A film of polyethylene terephthalate (PET) having a thickness of 100 μm was laminated as the spacer at both end portions of the glass substrate obtained in (2) described above on which chips were arranged and fixed.

A composition as a liquid resin composition of energy ray curing type containing 100 parts by mass of dimethyloltricyclodecane diacrylate [manufactured by KYOEISHA CHEMICAL Co., Ltd.; the trade name: “LIGHT ACRYLATE DCP-A”], 50 parts by mass of an epoxyacrylate of the bisphenol A type [manufactured by KYOEISHA CHEMICAL Co., Ltd.; the trade name: “EPOXYESTER 30002A”] and 2% by mass of 2-hydroxy-2-methyl-1-phenylpropan-1-one [manufactured by CIBA SPECIALTY CHEMICALS Company; the trade name: “DAROCURE 1173”] as a photopolymerization initiator was cast to coat the chips arranged and fixed on the resin layer described above [the viscosity when the composition was used for the coating: 1,250 mPa·S (25° C.)]. On the formed coating layer, a glass plate (the thickness: 1 mm) having the releasing treatment with a silicone resin, which was used as the support, was placed in a manner such that the face of the glass plate having the releasing treatment faced the coating layer, and an uncured coating layer was formed.

The obtained product was irradiated with ultraviolet light from a metal halide lamp as the light source at the side having the glass plate placed as described above at a luminance of 300 mW/cm² with a quantity of light of 1,000 mJ/cm², and the uncured coating layer was cured. Then, the layer of a resin sheet having embedded chips was separated from the glass plate and the glass substrate. A resin sheet having embedded chips having a thickness of about 100 μm as the thickness of the entire sheet in which 5×5 chips were embedded was obtained as described above. The result of the evaluation of the property for embedding is shown in Table 1.

### Example 2

A resin sheet having embedded chips was obtained in accordance with the same procedures as those conducted in Example 1 except that a resin composition of the thermosetting type was prepared by adding t-butyl peroxy-3,5,5-trimethylhexanoate [manufactured by Kayaku Akzo Corporation; the trade name: “TRIGONOX 42”] as a thermal polymerization initiator in place of the photopolymerization initiator “DAROCURE 1173” (described above), and the uncured coating layer was cured by the heat treatment at 100° C. for 30 minutes without irradiation with ultraviolet light. The viscosity of the resin composition when the composition was used for the coating was the same as that in Example 1. The result of the evaluation of the property for embedding is shown in Table 1.

### Example 3

A resin sheet having embedded chips was obtained in accordance with the same procedures as those conducted in Example 1 except that a resin composition containing 100 parts by mass of a modified epoxy acrylate resin [manufactured by DAICEL-CYTEC Company, Ltd.; the trade name: “Ebecryl 13708”] and 1.5 parts by mass of the photopolymerization initiator “DAROCURE 1173” (described above) was used as the liquid resin composition of the active energy ray curing type, and the composition was used for the solution casting by heating at 60° C. The viscosity of the resin composition of the ultraviolet light curing type was 4,100 mPa·s at 60° C. The result of the evaluation of the property for embedding is shown in Table 1.

### Example 4

A resin sheet having embedded chips was obtained in accordance with the same procedures as those conducted in Example 1 except that a composition containing 100 parts by mass of a urethane acrylate [manufactured by TOA GOSEI Co., Ltd.; the trade name: “ARONIX M-8060”] and 1.5 parts by mass of “DAROCURE 1173” (described above) as the photopolymerization initiator was used as the liquid resin composition of the active energy curing type. The viscosity of the resin composition was 10,000 mPa·s at 25° C. The result of the evaluation of the property for embedding is shown in Table 1.

### Example 5

A solution of an acrylic acid ester copolymer (the concentration of the solid components: 35% by mass) was obtained by bringing 80 parts by mass of butyl acrylate and 20 parts by mass of acrylic acid into reaction with each other in a mixed solvent of ethyl acetate and methyl ethyl ketone (the ratio of the amounts by mass: 50:50). To the obtained solution, 2-methacryloyloxyethyl isocyanate in an amount of 30 equivalent per 100 equivalent of acrylic acid in the copolymer was added. The reaction was allowed to proceed at 40° C. for 48 hours under the atmosphere of nitrogen, and a copolymer of the energy ray curing type having a weight-average molecular weight of 850,000 and having a group curable with energy ray at the side chain was obtained. Into the obtained solution of the copolymer of the energy curing type, 3.0 parts by mass of 2,2-dimethoxy-1,2-diphenylethan-1-one as the photo-polymerization initiator [manufactured by CIBA SPECIALTY CHEMICALS Company; the trade name: “IRGACURE 651”], 100 parts by mass of a composition containing polyfunctional monomers and oligomers of the energy ray curing type [manufactured by Dainichiseika Color & Chemicals Mfg. Co., Ltd.; the trade name: “14-29B(NPI)”] and 1.2 parts by mass of a crosslinking agent of a polyisocyanate compound [manufactured by TOYO INK MFG. CO., LTD.; the trade name: “ORIBAIN BHS-8515”] per 100 parts by mass of the solid components in the obtained solution of the copolymer of the energy curing type were dissolved. In the final step, the concentration of the solid components was adjusted at 40% by mass by adding methyl ethyl ketone. The resultant mixture was stirred until a uniform solution was obtained, and a liquid resin composition of the active energy ray curing type was obtained. The viscosity of the composition was 2,230 mPa·s at 25° C. The obtained composition was applied to the glass substrate obtained in Example 1(2) on which chips were arranged and fixed, and the resultant coating layer was dried at 90° C. for 2 minutes. This operation was repeated twice, and a layer of an uncured resin having a thickness of about 100 μm was formed. In accordance with the same procedures as those conducted in Example 1, a glass plate having the releasing treatment with a silicone resin was placed in a manner such that the face of the glass plate having the releasing treatment faced the coating layer. The same procedures as those conducted in Example 1 were conducted thereafter, and a resin sheet having embedded chips having a thickness of about 100 μm was obtained. The result of the evaluation of the property for embedding is shown in Table 1.

TABLE 1

| | Material of | | | | | |
|---|---|---|---|---|---|---|
| | energy curing type | | | Property for embedding | | |
| | | temperature and | | number of | | |
| | | viscosity when | | chip showing | amount of | |
| | | material is used | | gap between | protrusion | |
| | type of | for coating | | resin and | [h] (μm) | |
| | curing | (° C.) | (mPa · s) | chip | max | average |
| Example 1 | UV | 25 | 1250 | 0/50 | 15 | 7 |
| Example 2 | heat | 25 | 1250 | 0/50 | 13 | 7 |
| Example 3 | UV | 60 | 4100 | 0/50 | 10 | 5 |
| Example 4 | UV | 25 | 10000 | 0/50 | 10 | 5 |
| Example 5 | UV | 25 | 2230 | 0/50 | 6 | 3 |

Notes:
UV: ultraviolet light
max: the maximum value

### INDUSTRIAL APPLICABILITY

In accordance with the process of the present invention, the circuit substrate comprising a resin sheet having embedded circuit chips for controlling pixels of displays and the like can be efficiently produced with excellent quality and excellent productivity.

1-8. (canceled)

9. A process for producing a circuit substrate having a resin sheet having embedded circuit chips which is obtained by embedding circuit chips into a resin sheet, which comprises steps of:
(a) arranging and fixing circuit chips on a substrate for processing, (b) coating the substrate for processing on which the circuit chips have been arranged and fixed with a liquid material for forming a resin sheet of an energy curing type to form an uncured coating layer, (c) curing the uncured coating layer by impressing energy to form a layer of a resin sheet having embedded circuit chips, and (d) removing the substrate for processing from the layer of a resin sheet having embedded circuit chips.

10. The process for producing a circuit substrate according to claim 9, which comprises step (b′) between step (b) and step (c), said step (b′) comprising placing a support on the uncured coating layer.

11. The process for producing a circuit substrate according to claim 10, which comprises step (d′) in combination with step (d), said step (d′) comprising removing the support from the layer of a resin sheet having embedded circuit chips.

12. The process for producing a circuit substrate according to claim 9, wherein the substrate for processing has a layer of a silicone-based resin on a surface thereof.

13. The process for producing a circuit substrate according to claim 9, wherein a thickness of the resin sheet having embedded circuit chips is 50 to 500 mm.

14. The process for producing a circuit substrate according to claim 9, wherein, in step (b), viscosity of the liquid material for forming a resin sheet of an energy curing type is 1 to 100,000 mPa·s when the liquid material is used for coating.

15. The process for producing a circuit substrate according to claim 9, wherein the liquid material for forming a resin sheet of an energy curing type is a material of a thermosetting type or a material of an active energy ray curing type.

16. A circuit substrate having a resin sheet having embedded circuit chips which is obtained in accordance with a process described in claim 9.
